(19) United States
(12) Patent Application Publication
(10) Pub. No.: US 2026/0101706 A1
(43) Pub. Date: Apr. 9, 2026

(54) CONTAMINANT DETECTION DEVICE

(71) Applicant: SAMSUNG ELECTRONICS CO., LTD., Suwon-si (KR)

(72) Inventors: Hyejin JANG, Suwon-si (KR); Donghoon KWON, Suwon-si (KR)

(73) Assignee: SAMSUNG ELECTRONICS CO., LTD., Suwon-si (KR)

(21) Appl. No.: 19/078,722

(22) Filed: Mar. 13, 2025

(30) Foreign Application Priority Data
Oct. 8, 2024 (KR) 10-2024-0136952

(51) Int. Cl. H01L 21/67; H01L 21/66

(52) U.S. Cl. CPC H10P 72/0616; H10P 72/0428; H10P 74/235; H10P 74/273

(57) ABSTRACT

A contaminant detection device includes: a contact module configured to contact a wafer; a detection module on the contact module, the detector being configured to change color by reacting with a metal ion; and a sensing module configured to sense a color change of the detection module.

### CROSS-REFERENCE TO RELATED APPLICATION

This application is based on and claims priority under 35 U.S. C. § 119 to Korean Patent Application No. 10-2024-0136952, filed on Oct. 8, 2024, in the Korean Intellectual Property Office, the disclosure of which is incorporated by reference herein in its entirety.

### BACKGROUND

The present disclosure relates to a contaminant detection device.

The chemical mechanical polishing (CMP) process for semiconductors planarizes a wafer surface using chemical reactions and mechanical (physical) forces. The CMP process processes a wafer while supplying a polishing solution, such as slurry, to the wafer and applies pressure and rotation to a rotating polishing pad surface. The CMP is widely used to selectively remove materials for topography planarization and device structure formation in the semiconductor manufacturing.

After the CMP process is completed, contaminants (such as organic substances, abrasives, and slurries) remain on the wafer surface. Accordingly, a post-cleaning process (which is a post-CMP process) is performed, which removes the contaminants remaining on the wafer with a brush. However, in the post-cleaning process, some of the contaminants attached to the wafer adhere to and accumulate on the brush, which lead to reverse contamination of the wafer.

In addition, the contaminants remaining on the polishing pad during the CMP process can cause reverse contamination of new wafers in subsequent CMP processes.

To prevent the reverse contamination of wafers, brushes and polishing pads should be replaced regularly. However, a problem arises in that there is no way to sense contamination of brushes and polishing pads in advance, leading to uniform limit in the service life of brushes and polishing pads.

### SUMMARY

Provided are a contaminant detection device and a method to solve the above problems and attempt to provide a contaminant detection device that measures contamination of a polishing pad by Ti and W ions by arranging a detection component, which changes color by reacting with Ti and W ions, on a polishing pad that comes into contact with a wafer, allowing contamination of the polishing pad by Ti and W to be sensed through color change.

Provided are a contaminant detection device and a method to quantitatively measure contamination of a brush surface by arranging a detection component, which reacts with Ti and W ions, in a brush that comes into contact with a wafer, allowing a color change of the detection component to be sensed when the brush is contaminated.

According to an aspect of the disclosure, a contaminant detection device includes: a contact module configured to contact a wafer; a detection module on the contact module, the detector being configured to change color by reacting with a metal ion; and a sensing module configured to sense a color change of the detection module.

According to an aspect of the disclosure, a contaminant detection device includes: a head configured to mount a wafer thereon and rotate about a head axis; a detection module configured to react with a metal ion; a polishing pad on which the detection module is disposed to be exposed toward one surface of the wafer; and a sensing module connected to the head and configured to sense a color change of the detection module.

According to an aspect of the disclosure, a contaminant detection device includes: a brush comprising a detection module in at least a portion of a main body and a plurality of protrusions, wherein the detection module comprises a detection component configured to react with a metal ion; a cleaning module configured to clean the brush; and a sensing module that is mounted on the cleaning module and senses a color change of the detection module.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 illustrates a contaminant detection device according to an embodiment;

FIG. 2 illustrates a polishing pad on which a detection module is arranged in the contaminant detection device according to an embodiment;

FIGS. 3A and 3B illustrate a color change of a detection component due to a contaminant in the contaminant detection device according to an embodiment;

FIGS. 4A and 4B illustrate various embodiments of the detection module arranged on a polishing pad in the contaminant detection device according to an embodiment;

FIGS. 5A to 8C illustrate various arrangement structures of the detection module arranged on the polishing pad in the contaminant detection device according to FIG. 1;

FIGS. 9A and 9B illustrate a contaminant detection device according to another embodiment;

FIG. 10 is view for illustrating a color change of the detection component due to a contaminant in the contaminant detection device according to FIGS. 9A and 9B;

FIG. 11 illustrates a contaminant detection device according to another embodiment;

FIGS. 12A and 12B illustrate a sensing module in the contaminant detection device according to an embodiment; and

FIGS. 13 to 19 illustrate various embodiments of the detection module arranged in a brush in the contaminant detection device according to FIGS. 9A and 9B.

### DETAILED DESCRIPTION

In the following detailed description, only certain embodiments of the present disclosure have been shown and described, simply by way of illustration. The present disclosure can be variously implemented and is not limited to the following embodiments.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present disclosure is not limited thereto. In the drawings, the thickness of layers, films, panels, regions, etc., are exaggerated for clarity. In the drawings, for understanding and ease of description, the thickness of some layers and areas is exaggerated.

Throughout the specification, when a part is referred to as being “connected” to another part, this includes not only a case where they are “directly connected”, but also a case where they are “indirectly connected” with another member interposed therebetween”. In addition, unless explicitly described to the contrary, the word “comprise”, and variations such as “comprises” or “comprising”, will be understood to imply the inclusion of stated elements but not the exclusion of any other elements.

Further, when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above”or “on”in a direction opposite to gravity.

Further, in the present disclosure, when it is referred to as “on a plane”, it means when a target part is viewed from above. When it is referred to as “on a cross-section”, it means when the cross-section obtained by cutting a target part vertically is viewed from the side.

In the related art, during the CMP process, the polishing pad becomes contaminated due to contaminants on the wafer. To avoid reverse contamination of other wafers in subsequent CMP processes due to the contaminated polishing pad, it is necessary to assess a degree of contamination of the polishing pad and replace the polishing pad regularly.

However, if the polishing pad is contaminated with Ti (titanium), W (tungsten), and the like, there is no way to sense the contamination in advance, so the service life of the polishing pad is uniformly limited and replaced accordingly.

In the related art, after the CMP process, a cylindrical PVA (Poly Vinyl Acetal) brush is generally used as a brush for cleaning the wafer. However, during the process of cleaning the wafer, some of the contaminants attached to the wafer adhere to and accumulate on the PVA brush, leading to reverse contamination of the wafer.

To solve the reverse contamination problem in the related art, a brush cleaning process of cleaning the brush with a cleaning module is performed. However, it is difficult to solve the reverse contamination problem of the wafer through the brush cleaning process alone. Accordingly, the brush also needs to be replaced.

To determine when to replace the brush, the degree of contamination of the brush should be measured. In the related art, the degree of contamination of the brush is merely predicted by measuring a deterioration status of the brush surface using a separate measuring device or by analyzing the effluent discharged during the wafer cleaning process.

In the related art, accordingly, when the brush is contaminated with Ti, W, and the like, there is no way to sense the contamination in advance, so the service life of the brush needs to be uniformly limited.

Uniformly limiting the service life of the polishing pad and brush means, for example, uniformly limiting the usable period of the polishing pad and brush to a time point before defects occur due to reverse contamination of the wafer by Ti or W, for example.

According to the above method, the predicted service life will vary depending on various process variables, such as changes in each process condition, process environment, and material or characteristics of the polishing pad and brush. In this case, the service life needs to be set again for each process, which causes inconvenience.

In addition, since the degree of contamination is not measured quantitatively, it is not possible to consider cases where the service life is shortened due to unpredictable variables that occur in each process, making it difficult to manage contamination of polishing pads and brushes.

To avoid the above problems in the related art, a contaminant detection device 10 according to the present disclosure is to efficiently manage a degree of contamination of a polishing pad 110 and a brush 120 by quantitatively measuring the degree of contamination of a polishing pad 110 and a brush 120 through color change.

Hereinafter, the contaminant detection device 10 according to an embodiment of the present disclosure will be described in more detail with reference to the drawings.

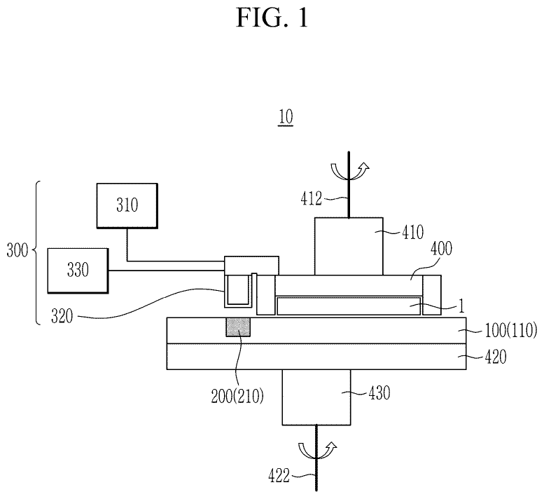

FIG. 1 illustrates the contaminant detection device 10 according to an embodiment. As shown in FIG. 1, the contaminant detection device 10 according to the present disclosure may include a contact module 100 in contact with a wafer 1, a detection module 200 that is arranged on the contact module 100 and changes color by reacting with at least one of a titanium (Ti) ion and a tungsten (W) ion, and a sensing module 300 that is configured to sense a color change of the detection module 200. In some embodiments, at least one of the contact module 100, the detection module 200 and the sensing module 300 may include a hardware component such as a processor, a circuit, or an electronic component (part) that performs or assists respective functions or operations of these structural elements 100, 200 and 300 described herein. For example, the sensing module 300 may be exchanged with a sensor and the detection module 200 may be exchanged with a detector.

The contact module 100 has a structure that contacts with the wafer 1, and may include a polishing pad 110 that polishes the wafer 1 during the CMP process and a brush 120 that cleans the wafer 1 after the CMP process.

The detection module 200 may include a detection component 210 that may detect contamination by metal ion substances such as Ti and W. The detection module 200 that is arranged on the contact module 100 may be arranged on the contact module 100 during a manufacturing operation of the contact module 100. That is, in a manufacturing operation of the polishing pad 110 and the brush 120, the detection module 200 may be manufactured to form parts of the polishing pad 110 and the brush 120.

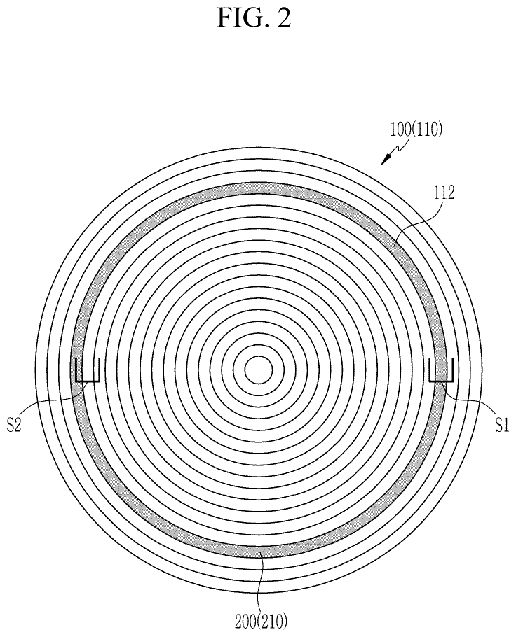

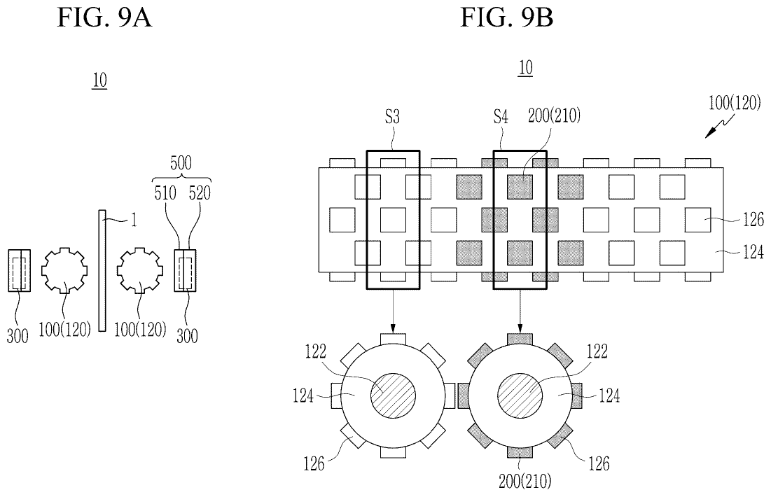

As described below, FIGS. 2 to 8C illustrate an embodiment in which the contact module 100 is the polishing pad 110, and FIGS. 9A to 19 illustrate an embodiment in which the contact module is the brush 120.

First, referring to FIG. 1, the contaminant detection device 10 according to an embodiment may include a polishing pad 110 in contact with a wafer 1, a detection module 200 arranged on the polishing pad 110 and changes color by reacting with at least one of Ti and W ions, and a sensing module 300 configured to sense (or detect) a color change of the detection module 200.

The polishing pad 110 may face one surface of the wafer 1 mounted on a head 400. The detection module 200 may be on the polishing pad 110 so as to be exposed toward one surface of the wafer 1.

The contaminant detection device 10 according to the present disclosure is configured to detect Ti and W ions among contaminants that contaminate the polishing pad 110.

The detection module 200 may include a detection component 210 that detects Ti ions and a detection component 210 that detects W ions.

The (first) detection component 210 that detects Ti ions may include a chromotropic acid, such as 1,8-dihydroxynaphthalene-3,6-disulphonic acid. The (second) detection component 210 that detects W ions may include 1,5-diaminonaphthalene and 5-bromo-salicylaldehyde.

In an embodiment, in the detection module 200, the (first) detection component 210 that reacts with Ti ions and the (second) detection component 210 that reacts with W ions are not mixed and arranged. This means that the two detection components 210 are not mixed and arranged at one location. The respective detection components 210 can be arranged at different locations.

The contaminant detection device 10 according to another embodiment may include a head 400 that mounts a wafer 1 on the head 400 and rotates about a head axis 412, a polishing pad 110 on which a detection module 200 that reacts with at least one of Ti and W ions is arranged so as to be exposed toward one surface of the wafer 1 mounted on the head 400, and a sensing module 300 that is connected to the head 400 and that is configured to sense a color change of the detection module 200.

The sensing module 300 may include a light source 310 that irradiates a beam, an optical window 320 that is mounted on the head 400 and allows the irradiated beam to enter toward the polishing pad 110, and a spectrometer 330 that receives the beam reflected from the polishing pad 110 and re-entering through the optical window 320 to measure a spectrum of the beam.

As shown in FIG. 1, the optical window 320 is mounted on one side of the head 400, and the optical window 320 may also move along with movement of the head 400. That is, depending on each rotation of the polishing pad 110 and the head 400, a position of the head 400 arranged on the polishing pad 110 changes. Accordingly, the optical window 320 can move on the polishing pad 110 together with the head 400.

The contaminant detection device 10 may further include a head driver 410 that is connected to the head 400 and that rotates the head 400 about the head axis 412.

In an embodiment, the contaminant detection device 10 may further include, as a configuration arranged below the polishing pad 110, a platen 420 to which the polishing pad 110 is fixed on an upper side, and a platen driver 430 that rotates the platen 420 about a platen axis 422.

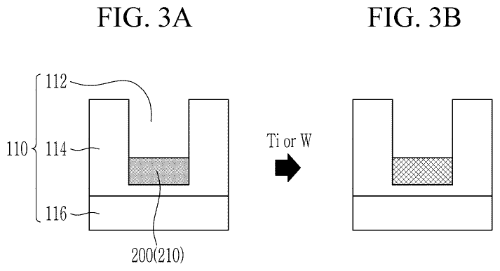

FIG. 2 illustrates the polishing pad on which the detection module is arranged in the contaminant detection device according to an embodiment. FIGS. 3A and 3B illustrate a color change of the detection component due to a contaminant in the contaminant detection device according to an embodiment.

FIG. 2 illustrates the polishing pad 110 as viewed from above, allowing for confirmation of an arrangement structure of the detection module 200 arranged on the polishing pad 110. The detection module 200 arranged on the polishing pad 110 may be arranged in a linear form as shown in FIG. 2. In an embodiment, the detection module may have a concentric circular form.

FIGS. 3A and 3B illustrates side cross-sectional views of the polishing pad 110, taken along line S1 in FIG. 2. A structure of a groove 112 for the detection module 200 arranged on the polishing pad 110 can be confirmed.

Referring to FIGS. 3A and 3B, the polishing pad 110 may include a top pad 114. The upper surface of the top pad 114 comes into contact with the wafer 1. the polishing pad 110 may also include a sub-pad 116 arranged below the top pad 114, and a groove 112 that has a step (i.e., an area or space) from the upper surface of the top pad 114 and is provided in a concentric circular form on the polishing pad 110. The groove 112 has the step from one surface that comes into contact with the wafer 1.

The detection module 200 may be arranged anywhere on the top pad 114 where the polishing pad 110 is exposed toward the wafer 1.

In an embodiment, the detection module 200 may be arranged so as to be exposed to the groove 112, or may also be arranged so as to be exposed to at least a portion of one surface of the polishing pad 110 (an area other than the groove 112).

First, FIGS. 2, 3A, and 3B show a case where the detection module 200 is arranged on the top pad 114 so as to constitute at least a portion of surfaces forming the groove 112. That is, the detection module 200 is arranged so as to constitute an upper surface of the groove 112.

The detection module 200 including a detection component 210, shown in FIG. 3A, has a feature of reacting with at least one of Ti and W ions, resulting in a color change as shown in FIG. 3B.

The detection component 210 that detects Ti ions is 1,8-dihydroxynaphthalene-3,6-disulphonic acid. The detection component 210 is red before a reaction but has the property of changing to purple by reacting with Ti ions.

The detection component 210 that detects W ions is 1,5-diaminonaphthalene and 5-bromo-salicylaldehyde. The detection component 210 is colorless before a reaction but has the property of changing to yellow by reacting with W ions.

For example, in a case where the detection component 210 that detects W ions is applied to the polishing pad 110, the polishing pad 110 has a color unique to the polishing pad before reacting with the W ions but changes to yellow after reacting with the W ions.

The detection module 200 does not mix the detection component 210 that reacts with Ti ions and the detection component 210 that reacts with W ions.

If mixed, it may be not easy to determine a color change before and after change upon reaction with at least one of the Ti and W ions. Therefore, each detection component 210 may be arranged independently.

However, the respective detection components 210 may be arranged in different areas on the polishing pad 110. In this case, by sensing the color change of each detection component 210 arranged in each area, it is possible to determine whether the polishing pad is contaminated with both Ti and W.

In the embodiments described herein, the detection module 200 is described as including the detection component 210 configured to detect Ti ions or W ions. However, the disclosure is not limited thereto, and the detection module 200 may include a different detection component configured to detect metal ions other than Ti ions and W ions.

The sensing module 300 may be configured to sense the change of the detection component 210 from red to purple, thereby confirming that the polishing pad 110 is contaminated with Ti.

In addition, the sensing module 300 can sense the change of the detection component 210 from the color of the polishing pad 110 to yellow, thereby confirming that the polishing pad 110 is contaminated with W.

Referring to FIGS. 1, 3A, and 3B, the process of sensing a color change by the sensing module 300 may involve a light source 310 first irradiating a beam toward the polishing pad 110 through an optical window 320 arranged on one surface of a cleaner 510. The beam passing through the optical window 320 and directed toward the polishing pad 110 is reflected from the polishing pad 110 and re-enters the optical window 320. In this case, the spectrometer 330 can measure a spectrum of the beam re-entering through the optical window 320.

Here, contamination of the polishing pad 110 can be measured by measuring a change in intensity of the beam that passes through the optical window 320, is transmitted to the polishing pad 110, is reflected, and then re-enters the optical window 320.

The detection module 200 is initially in a state of the detection component 210 that is red (before reacting with Ti ions) or colorless (before reacting with W), and changes to purple (after reacting with Ti ions) and yellow (after reacting with W), respectively when reacting with Ti and W ions, i.e., when contaminated. In this case, the change in intensity of the beam according to the color change of the detection module 200 is measured.

Since the measured intensity changes higher or lower depending on the color change, the degree of contamination can be quantitatively measured through the change in the intensity above.

Using a separate analysis device, it may be also possible to analyze the degree of contamination of the polishing pad 110 more specifically through results measured by the spectrometer 330.

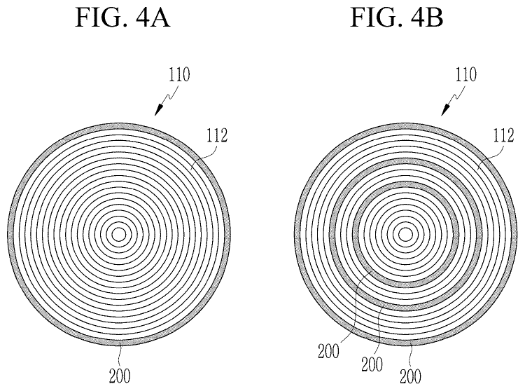

FIGS. 4A and 4B illustrate various embodiments of the detection module arranged on a polishing pad in the contaminant detection device according to an embodiment.

FIG. 2 corresponds to an embodiment in which the detection module 200 is arranged to form the upper surface of the groove 112 and is arranged in the form of one concentric circle.

FIGS. 4A and 4B illustrate detection modules 200, arranged on the polishing pad 110, in a concentric circular form with different diameters from that of the detection module 200 in FIG. 2.

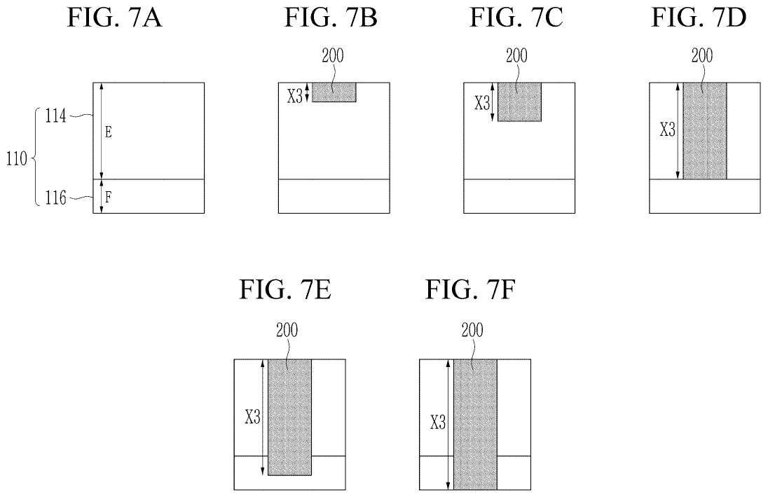

The detection module 200 may be arranged on the upper surface of the groove 112, but the arrangement structure of the detection module 200 is not limited thereto. Referring to FIGS. 7A to 7F described below, the detection module 200 may also be arranged in an area other than the groove 112 of the polishing pad 110. The detection module 200 may be arranged to constitute one surface of the groove 112, or, depending on embodiments, may be arranged to constitute a protruding upper surface of the polishing pad 110 other than the groove 112.

In the drawings (e.g., FIGS. 4A and 4B), the detection module 200, which has a linear form, is shown only in a concentric circular form. Without being limited thereto, the detection module 200, which has a linear form, may also have an arc form with various lengths, in addition to a concentric circular form.

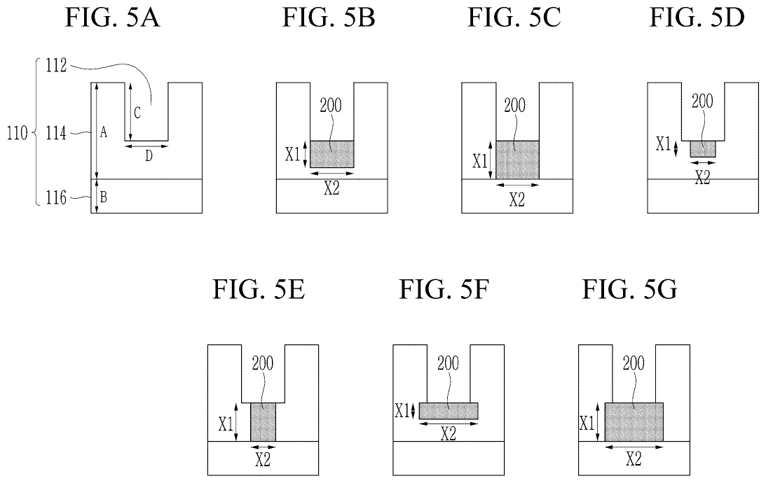

Various structures of the detection module 200 arranged on the polishing pad 110 will be described below with reference to FIGS. 5A to 8C.

FIGS. 5A to 8C illustrate various arrangement structures of the detection module arranged on the polishing pad in the contaminant detection device according to FIG. 1.

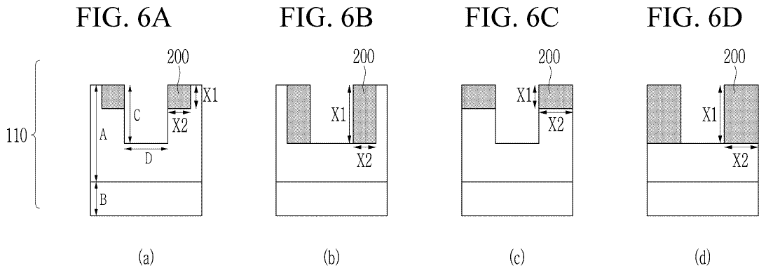

FIGS. 5A to 6D show an embodiment in which the detection module 200 is arranged in an area of the polishing pad 110 where the groove 112 is provided.

FIGS. 5A to 6D show a case where the detection module 200 is arranged on the top pad 114 so as to constitute at least a portion of the surfaces forming the groove 112, and FIGS. 7A to 7F shows an embodiment where the detection module 200 is arranged on the polishing pad 110 so as to constitute at least a portion of the upper surface of the top pad 114.

First, FIGS. 5A to 5G show a case where the detection module 200 is arranged so as to be exposed through at least a portion of the upper surface of the groove 112. FIGS. 6A to 6D show a case where the detection module 200 is arranged so as to be exposed through at least a portion of the side surface of the groove 112.

The structure of the polishing pad 110 shown in FIGS. 5A to 6D corresponds to the appearance of the polishing pad 110 provided with the groove 112 and is equivalent to the S1 cross-sectional structure shown in FIG. 2.

FIG. 5A illustrates a cross-sectional view of the polishing pad 110 on which the detection module 200 is not arranged. This is shown so as to explain FIGS. 5B to 5G and FIGS. 6A to 6D.

Referring to FIG. 5A, a height of the top pad 114 is denoted as ‘A’, a height of the sub-pad 116 is denoted as ‘B’, a height of the groove 112 provided on the top pad 114 is denoted as ‘C’, and a width of the groove 112 is denoted as ‘D’.

FIGS. 5B to 5G and FIGS. 6A to 6D illustrate that the detection module 200 is arranged to be or correspond to at least a portion of the surfaces forming the groove 112. Here, a height of the detection module 200 is denoted as ‘X1’, and a width of the detection module 200 is denoted as ‘X2’.

First, FIG. 5B shows a case where the range of ‘X1’, which is the height of the detection module 200, is X1<(A-C)×½, and the range of ‘X2’, which is the width of the detection module 200, is D×½≤X2≤D.

FIG. 5C shows a case where (A-C)×½≤X1≤(A-C) and D×½≤X2≤D.

FIG. 5D shows a case where X1<(A-C)×½ and X2<D×½×.

FIG. 5E shows a case where (A-C)×½≤X1≤(A-C) and X2<D×½.

FIG. 5F shows a case where X1<(A-C)×½and D≤X2.

FIG. 5G shows a case where (A-C)×½≤X1≤(A-C) and D≤X2.

FIG. 6A shows a case where X1<C×½ and X2<D×½.

FIG. 6B shows a case where C×½≤X1≤C and X2<D×½.

FIG. 6C shows a case where X1<C×½ and D×½≤X2≤D.

FIG. 6D shows a case where C×½≤X1≤C and D×½≤X2≤D.

Although not urban, a case where X2 is equal to or greater than D is also possible.

As shown in FIGS. 5A to 6D, the detection module 200 may be variously arranged on the polishing pad 110 so as to constitute one surface of the groove 112.

FIGS. 7A to 7F show an embodiment in which the detection module 200 is arranged in an area of the polishing pad 110 where the groove 112 is not provided. The structure of the polishing pad 110 shown in FIGS. 7A to 7F corresponds to the polishing pad 110 of a part other than the groove 112 and is equivalent to the S2 cross-sectional structure shown in FIG. 2.

FIGS. 7B to 7F show a case where the detection module 200 is arranged so as to be exposed to at least a portion of one surface of the polishing pad 110, other than the groove 112.

FIG. 7A is shown as an example to explain FIGS. 7B to 7F.

Referring to FIG. 7A, a height of the top pad 114 is denoted as ‘E’, and a height of the sub-pad 116 is denoted as ‘F’, and referring to FIG. 7B, a height of the detection module 200 provided on the top pad 114 is denoted as ‘X3’.

First, FIG. 7B shows a case where the range of ‘X3’, which is the height of the detection module 200, is X3<E×⅓.

FIG. 7C shows a case where E×⅓≤X3<E×½, and FIG. 7D shows an embodiment where E×½≤X3≤E.

FIG. 7E shows a case where E<X3<E+(F×½), and FIG. 7F shows an embodiment where E+(F×½)<X3≤E+F.

As shown in FIGS. 7B to 7F, the detection module 200 can also be variously arranged in an area of the polishing pad 110 where the groove 112 is not provided.

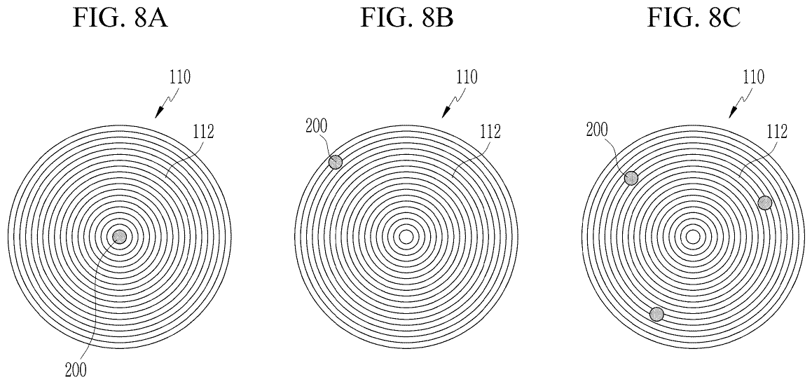

FIGS. 8A to 8C illustrate the polishing pad 110 as viewed from above, allowing for confirmation of an arrangement structure of the detection module 200 arranged on the polishing pad 110. The detection module 200 arranged on the polishing pad 110 may be arranged in a point form.

Although a circular point form is shown in the above drawings, the shape is not limited. In some embodiments, the detection module 200 may have various forms, such as a quadrilateral, a rhombus, a trapezoid, and the like.

According to the contaminant detection device 10 of the present disclosure, the detection module 200 may be arranged to form at least one of a point and a line. That is, the detection module 200 may be arranged in a point form, a line shape, or a structure in which both point and line forms are arranged simultaneously.

The detection module 200 is arranged on the polishing pad 110 by adjusting its position and shape in consideration of a contamination pattern of the wafer 1, allowing for a more efficient determination of the degree of contamination of the polishing pad 110.

The contaminant detection device 10 for detecting contamination of a brush 120 will be described with respect to FIGS. 9A to 19.

The brush 120 according to the present disclosure is a brush 120 used in a CMP post-cleaning process, and has a structure in which a plurality of protrusions 126 protrude from a surface of the cylindrical brush 120 so as to increase the efficiency of removing residues on the wafer 1. The brush 120 performs a rotational motion about its longitudinal axis, and in this case, the plurality of protrusions 126 contact with the wafer 1 to remove residues on the wafer 1.

The contaminant detection device 10 according to the present disclosure is to sense contamination of the brush 120 contaminated with Ti and W during the process of cleaning the wafer 1 as described above.

The detection module 200 arranged on the brush 120 changes color by reacting with Ti and W ions, and determines the presence or absence of contamination by sensing the color change.

FIGS. 9A and 9B illustrate a contaminant detection device according to another embodiment.

FIG. 9A shows the contaminant detection device 10, and FIG. 9B shows the brush 120. In FIG. 9B, cross-sections of the brush 120 taken along lines S3 and S4 are shown.

As shown in FIGS. 9A and 9B, the contaminant detection device 10 according to another embodiment may include a brush 120 that comes into contact with at least one surface of a wafer 1, a detection module 200 that is arranged in the brush 120 and changes color by reacting with at least one of Ti and W ions, and a sensing module 300 that is configured to sense a color change of the detection module 200.

The contact module 100 may include a pair of brushes 120 arranged on both sides of the wafer 1, respectively, and the detection module 200 may be arranged so as to be exposed to each brush 120.

Each brush 120 of the pair of brushes 120 may include a core 122 that rotates about a longitudinal axis, a main body 124 surrounding the core 122, and a plurality of protrusions 126 protruding from the main body 124.

The detection module 200 may include a detection component 210 that changes color by reacting with at least one of Ti and W ions. The detection module 200 can be arranged in at least a portion of the main body 124 and the plurality of protrusions 126 of each brush 120.

FIG. 9A shows an example where the sensing module 300 is arranged in a cleaning module 500. The sensing module 300 is arranged close to (or adjacent to) the brush 120 to be able to sense a color change of the detection module 200 arranged in the brush 120, and the arrangement position of the sensing module 300 is not limited.

FIG. 9B shows an aspect where the detection module 200 is arranged in some protrusions 126 among the plurality of protrusions 126 of the brush 120.

The sensing module 300 is responsible for sensing whether there is a change in the color of the detection module 200 arranged in the brush 120, i.e., the detection component 210.

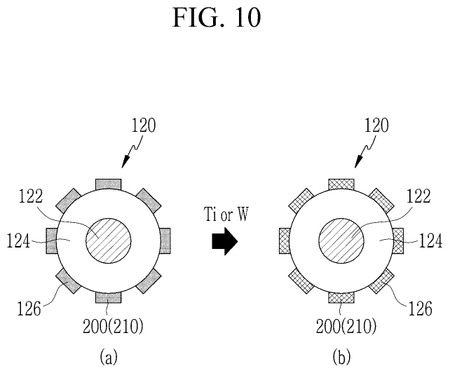

FIG. 10(a) and 10(b) illustrate a color change of the detection component due to a contaminant in the contaminant detection device according to FIGS. 9A and 9B.

FIG. 10(a) and 10(b) are cross-sectional view perpendicular to the longitudinal direction of the brush 120 (taken along line S4 of FIG. 9B), allowing for confirmation of the position of the detection module 200 arranged in the brush 120.

When the brush 120 is contaminated with Ti or W, the color of the detection module 200 changes, and the sensing module 300 senses this color change to predict the degree of contamination of the brush 120.

In FIG. 10(a) and 10(b), the detection module 200 is arranged in the protrusions 126 of the brush 120. The detection module 200 including a detection component 210, shown in FIG. 10(a), has a feature of reacting with at least one of Ti and W ions, resulting in a color change as shown in FIG. 10(b).

However, the (first) detection component 210 that reacts with Ti ions and the (second) detection component 210 that reacts with W are not mixed. Each detection component 210 may be arranged separately without being mixed.

If mixed, it may be not easy to determine a color change before and after change upon reaction with at least one of the Ti and W ions. Therefore, each detection component 210 may be arranged independently.

The (first) detection component 210 that detects Ti ions is 1,8-dihydroxynaphthalene-3,6-disulphonic acid. The detection component 210 is red before reaction but has the property of changing to purple as a result of reaction with Ti ions.

The (second) detection component 210 that detects W ions is 1,5-diaminonaphthalene and 5-bromo-salicylaldehyde. The detection component 210 is colorless before a reaction but has the property of changing to yellow by reacting with W ions.

For example, in a case where the detection component 210 that detects W ions is applied to the brush 120, the brush 120 has a color unique to the brush before reacting with the W ions but changes to yellow after reacting with the W ions.

The sensing module 300 may be configured to sense the change of the detection component 210 from red to purple, thereby confirming that the brush 120 is contaminated with Ti.

In an embodiment, the sensing module 300 can sense the change of the detection component 210 from the initial color of the brush 120 to yellow, thereby confirming that the brush 120 is contaminated with W.

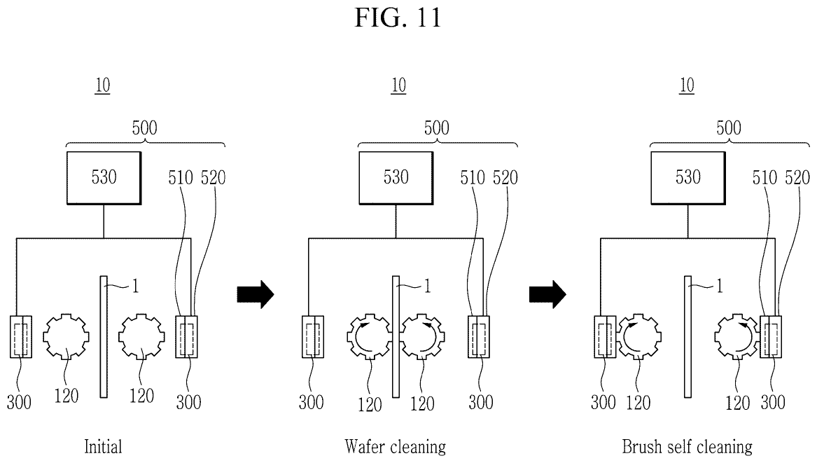

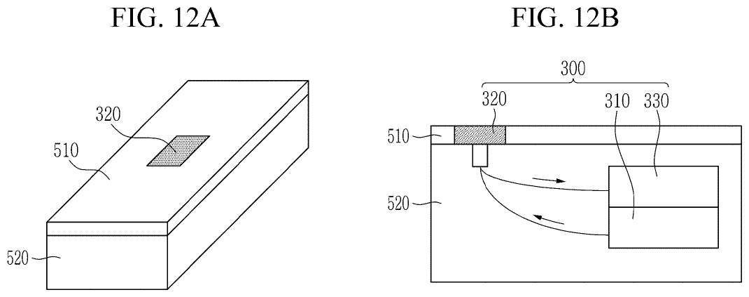

FIG. 11 illustrates a contaminant detection device according to another embodiment, and FIGS. 12A and 12B illustrate a sensing module in the contaminant detection device according to an embodiment.

Referring to FIGS. 10 to 12B, the contaminant detection device 10 according to another embodiment may include a brush 120 on which a detection module 200 including a detection component 210 that reacts with at least one of Ti and W ions is arranged on at least a portion of a main body 124 and a plurality of protrusions 126, a cleaning module 500 that cleans the brush 120, and a sensing module 300 that is mounted on the cleaning module 500 and senses a color change of the detection module 200.

The cleaning module 500 may include a cleaner 510 that comes into contact with the brush 120 on one side and cleans the brush 120, and a supporter 520 that is connected to the other side of the cleaner 510 and supports the cleaner 510. In addition, the cleaning module may further include a cleaning driver 530 that drives the cleaning module 500.

As shown, the sensing module 300 may be arranged in the cleaner 510 and the supporter 520.

FIG. 11 shows the brushes 120 arranged on both sides of the wafer 1 and the cleaning module 500 arranged on a side of each brush 120.

The brush 120 may be cleaned by the cleaner 510 of the cleaning module 500 after cleaning the wafer 1 is completed. The cleaner 510 comes into contact with the brush 120 and cleans the brush 120, and in this case, the brush 120 can rotate about its longitudinal axis.

Referring to FIG. 11, in an initial operation, the brush 120 is in a standby state. In a wafer cleaning operation, the pair of brushes 120 moves close to the wafer 1 so that each brush comes into contact with the wafer 1, thereby cleaning the wafer 1. In a brush self-cleaning operation, which is performed after the wafer cleaning operation is completed, the pair of brushes 120 moves close to the cleaning modules 500 and is cleaned in contact with the cleaners 510.

A process of sensing whether the color of the detection module 200 arranged in the brush 120 has changed is carried out in a state where the brushes 120 are moved close to the cleaners 510 for brush self-cleaning.

When the brush 120 moves close to the cleaning modules 500, the sensing module 300 arranged in the cleaning module 500 can sense a color change of the detection module 200 of the brush 120.

FIG. 12A illustrates the optical window 320 arranged on the surface of the cleaner 510. FIG. 12B shows a side of the cleaner 510 and the supporter 520, allowing for confirmation of the arrangement structure of the light source 310, the optical window 320, and the spectrometer 330.

The sensing module 300 may include a light source 310 that irradiates a beam, an optical window 320 that is mounted on one side of the cleaner 510 to be directed toward the brush 120 and allows the beam to enter toward the brush 120, and a spectrometer 330 that receives the beam reflected from the brush 120 and re-entering through the optical window 320 to measure a spectrum of the beam.

In the supporter 520, the light source 310 that irradiates a beam and the spectrometer 330 that receives the beam reflected from the brush 120 and re-entering through the optical window 320 to measure a spectrum of the beam may be arranged. The optical window 320, which is arranged to be directed toward the brush 120 and allows a beam to enter toward the brush 120, may be arranged on the cleaner 510.

The position of the optical window 320 arranged on the cleaner 510 is not limited to a single point, and the optical window 320 can be arranged at any location on the cleaner 510. In terms of sensing the color change of the detection module 200 of the brush 120 through the optical window 320, it is preferable for the position of the optical window 320 arranged on the cleaner 510 to correspond to the detection module 200 of the brush 120.

Referring to FIG. 12B, the process of detecting a color change may involve the light source 310, arranged in the cleaning module 500, first irradiating a beam toward the brush 120 through the optical window 320 arranged on one surface of the cleaner 510. The beam passing through the optical window 320 and directed toward the brush 120 is reflected from the brush 120 and re-enters the optical window 320. In this case, the spectrometer 330 can measure a spectrum of the beam re-entering through the optical window 320.

Here, contamination of the brush 120 is measured by measuring a change in intensity of the beam that passes through the optical window 320, is transmitted to the brush 120, is reflected, and then re-enters the optical window 320.

The detection module 200 is initially in a state of being red or colorless, and changes to purple and yellow, respectively, when contaminated with Ti and W. In this case, the change in intensity of the beam according to the color change of the detection module 200 is measured.

Since the measured intensity changes higher or lower depending on the color change, the degree of contamination can be quantitatively measured through the change in the intensity above.

The results measured by the spectrometer 330 can be used to analyze the degree of contamination of the brush 120 through a separate analysis device.

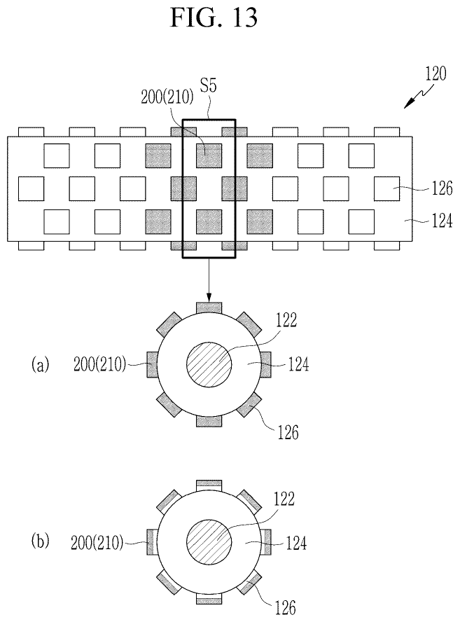

FIGS. 13 to 19 illustrate various embodiments of the detection module 200 arranged in the brush 120 in the contaminant detection device according to FIGS. 9A and 9B.

In the contaminant detection device 10 according to the present disclosure, the detection module 200 may be arranged at various locations in the brush 120. That is, the detection module 200 may be arranged in at least a portion of the main body 124 and the plurality of protrusions 126 of the brush 120.

The detection module 200 may be arranged in the main body 124 of the brush 120, in the protrusions 126, or in both the main body 124 and the protrusions 126. Here, the content of the arranged detection component 210 may be the same or different depending on the locations.

For example, the detection module 200 arranged in the main body 124 may include the same content of the detection component 210 in an inner side portion 124a, which is close to an inner side surface where the main body 124 is in contact with the core 122, and in an outer side portion 124b, which is close to an outer side surface where the main body 124 is in contact with the plurality of protrusions 126.

In an embodiment, the detection module 200 arranged in the main body 124 may include different contents of the detection component 210 in the inner side portion 124a and in the outer side portion 124b, respectively.

In an embodiment, the detection module 200 arranged in the protrusions 126 may include different contents of the detection component 210 depending on distance from the main body 124, but may also include the same content of the detection component 210 throughout the entire detection module 200, regardless of the distance from the main body 124.

One or more embodiments of the detection module 200 arranged in the brush 120 will be described with reference to FIG. 13(a) to 19(d).

FIG. 13(a) and 13(b) show cross-sections taken along line S5. As shown in FIG. 13(a) and 13(b), the brush 120 according to the present disclosure has a structure including the core 122, the main body 124 surrounding the core 122, and the plurality of protrusions 126 protruding from the main body 124.

In FIG. 13(a) and 13(b), the detection component 210 may be arranged in a portion of the plurality of protrusions 126. The brush 120 has the detection module 200 arranged in the protrusions 126 located in an area indicated by S5, and the detection module 200 is not arranged in the main body 124.

FIG. 13(a) and 13(b) correspond to an embodiment of the brush 120 in which the detection module 200 is arranged in the protrusions 126 located in the middle of one end and the other end when the starting and ending points in the longitudinal direction of the main body 124 are set as one end and the other end, respectively. That is, the brush 120 shown in FIG. 13(a) and 13(b) has a form in which the detection module 200 is arranged only in some protrusions 126.

As shown in FIG. 13(a), the detection module 200 arranged in each protrusion 126 may include the same content of the detection component 210 throughout the entire detection module 200, regardless of the distance from the main body 124. That is, in FIG. 13(a), the entire detection module 200 is depicted in the same shade, which means that the detection module includes the same content of the detection component 210.

The detection module 200 shown in FIG. 13(b) includes the contents of the detection component 210 arranged differently depending on the distance from the main body 124. The detection module 200 is shown such that the shade becomes darker as it is farther from the main body 124. This means that the content of the detection component 210 becomes higher as it is farther from the main body 124.

FIG. 13(b) corresponds to an embodiment of the brush 120 in the S5 cross-section, where no or almost no detection component 210 is included in the lower end of the detection module 200 in contact with the main body 124, and the content of the detection component 210 becomes higher as it is closer to the upper end of the detection module 200.

As shown in FIG. 13(a) and 13(b), the brush 120 according to the present disclosure may have the detection module 200 arranged in some of the plurality of protrusions 126, and each detection module 200 may include the same content of the detection component 210 throughout the entire detection module 200, regardless of the distance from the main body 124, or may include different contents of the detection components 210 depending on the distance from the main body 124.

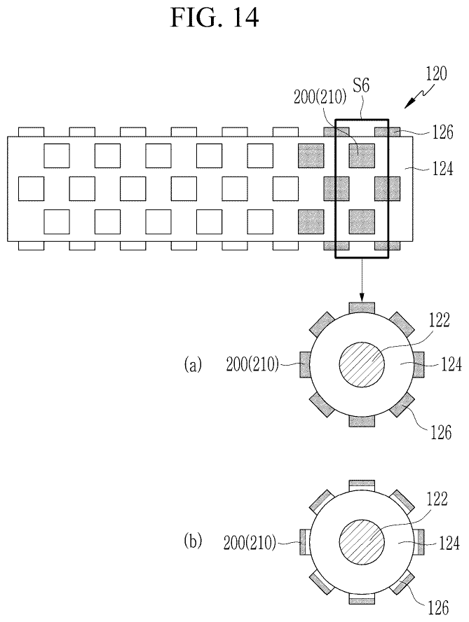

FIG. 14(a) and 14(b) show cross-sections taken along line S6. FIG. 14(a) and 14(b) correspond to an embodiment in which the detection module 200 is arranged only in the protrusions 126 located at one end of the main body 124 when the starting and ending points in the longitudinal direction of the main body 124 are set as one end and the other end, respectively.

FIG. 14(a) shows an embodiment in which the detection module 200 includes the same content of the detection component 210 throughout the entire detection module 200, regardless of the distance from the main body 124.

FIG. 14(b) shows an embodiment in which the detection module 200 includes the different contents of the detection component 210 depending on the distance from the main body 124. That is, the detection module 200 arranged in the protrusions 126 arranged at one end of the main body 124 includes a higher content of the detection component 210 as it is farther from the main body 124.

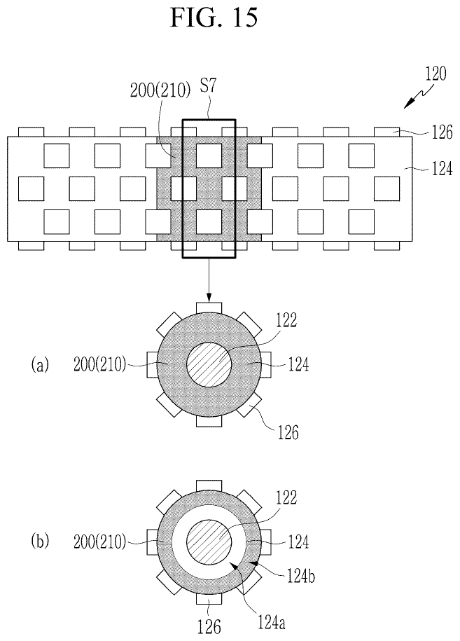

FIG. 15(a) and 15(b) show cross-sections taken along line S7. In FIG. 15(a) and 15(b), the detection module 200 is arranged in a portion of the main body 124 of the brush 120. That is, when the starting and ending points in the longitudinal direction of the main body 124 are set as one end and the other end, respectively, the detection module 200 may be arranged in the main body 124 at a middle position (S7) between the one end and the other end.

As shown in FIG. 15(a), the detection module 200 arranged in the main body 124 may include the same content of the detection component 210 in the inner side portion 124a, which is close to the inner side surface where the main body 124 is in contact with the core 122, and in the outer side portion 124b, which is close to the outer side surface where the main body 124 is in contact with the plurality of protrusions 126. The entire detection module 200 is depicted in the same shade, which means that the detection module includes the same content of the detection component 210.

FIG. 15(b) shows an embodiment in which the detection module 200 includes the different contents of the detection component 210 included in the main body 124. The detection module 200 may include the different contents of the detection component 210 in the inner side portion 124a, which is close to the inner side surface where the main body 124 is in contact with the core 122, and in the outer side portion 124b, which is close to the outer side surface where the main body 124 is in contact with the plurality of protrusions 126. That is, the content of the detection component 210 included in the detection module 200 becomes higher as it is closer to the outer side portion 124b of the main body 124.

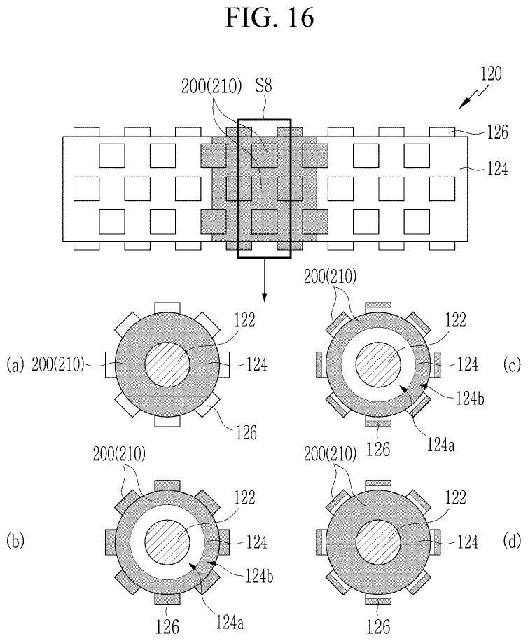

FIG. 16(a) to 16(d) show cross sections taken along line S8. In FIG. 16(a) to 16(d), the detection module 200 is arranged in portions of the main body 124 and the protrusions 126 of the brush 120.

In an embodiment, when the starting and ending points in the longitudinal direction of the main body 124 are set as one end and the other end, respectively, the detection module 200 is arranged in both the main body 124 and the protrusions 126 at a middle position S8 between the one end and the other end.

First, as shown in FIG. 16(a), the detection modules 200 arranged in the main body 124 and the protrusion 126 may both include the same content of the detection component 210.

FIG. 16(a) corresponds to an embodiment in which the detection module 200 includes the same content of the detection component 210 in each of the inner side portion 124a, which is close to the inner side surface where the main body 124 is in contact with the core 122, and the outer side portion 124b, which is close to the outer side surface where the main body 124 is in contact with the plurality of protrusions 126, and the protrusions 126 formed on the surface of the main body 124 in which the detection module 200 is arranged also include the same content of the detection component 210.

In FIG. 16(b), the detection module 200 arranged in the main body 124 has a higher content of the detection component 210 included in the detection module 200 as it is closer to the outer side portion 124b of the main body 124. In addition, the detection module 200 arranged in the protrusions 126 includes the same content of the detection component 210 throughout the entire detection module 200, regardless of the distance from the main body 124.

FIG. 16(c) shows an embodiment where the content of the detection component 210 included in the detection module 200 arranged in the main body 124 and the protrusions 126 is different depending on the location.

First, the detection module 200 arranged in the protrusions 126 is shown so that the shade becomes darker as it is farther from the main body 124, which means that the content of the detection component 210 becomes higher as it is farther from the main body 124.

That is, the brush 120 in the S8 cross-section shown in FIG. 16(c) corresponds to a case where almost no detection component 210 is included in the lower end of the detection module 200 in contact with the main body 124, and the content of the detection component 210 becomes higher as it is closer to the upper end of the detection module 200.

In an embodiment, the detection module 200 in the main body 124 includes the different contents of the detection component 210 in each of the inner side portion 124a, which is close to the inner side surface where the main body 124 is in contact with the core 122, and the outer side portion 124b, which is close to the outer side surface where the main body 124 is in contact with the plurality of protrusions 126, and the content of the detection component 210 included in the detection module 200 becomes higher as it is closer to the outer side portion 124b of the main body 124.

In FIG. 16(d), the detection module 200 arranged in the main body 124 includes the same content of the detection component 210 in each of the inner side portion 124a, which is close to the inner side surface where the main body 124 is in contact with the core 122, and the outer side portion 124b, which is close to the outer side surface where the main body 124 is in contact with the plurality of protrusions 126, and the detection module 200 arranged in the protrusions 126 includes a higher content of the detection component 210 as it is farther from the main body 124.

In the brush 120 according to the present disclosure, at least one detection module 200 may be arranged in at least two or more sections divided along the longitudinal direction of the main body 124.

In an embodiment, when a plurality of detection modules 200 are arranged in each section as described above, the positions at which each detection module 200 is arranged may be different or may be the same.

In an embodiment, in a state that three sections are divided, the detection module 200 may be arranged in the protrusions 126 in one section, while the detection module 200 may not be arranged in the remaining two sections. Alternatively, the detection module 200 may be arranged in the main body 124 in one section, while the detection module 200 may be arranged in the protrusions 126 in the other two sections.

In other embodiments, the content of the detection component 210 included in each detection module 200 may be different. For example, assuming that three sections are divided, the detection modules 200 may be arranged in the main body 124 in both two sections, while the detection module 200 may not be arranged in the remaining one section. In this case, the contents of the detection component 210 included in the respective detection modules 200 arranged in the two sections may be different.

In each of FIG. 13(a) to 16(d), the longitudinal direction of the main body 124 is divided into one end and the other end, with the description provided for each of one end, the other end, and the middle position between the one end and the other end.

In FIG. 13(a) to 16(d), the division into three sections and the accompanying descriptions are provided merely as an example, and the division into three sections is not necessarily required. That is, the division into multiple sections is possible.

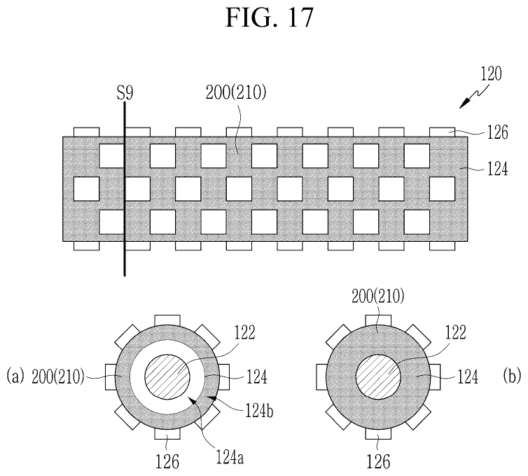

The brush 120 shown in FIG. 17(a) to 19(d) corresponds to a case where, unlike FIG. 13(a) to 16(d), the brush 120 is not divided into multiple sections along the longitudinal direction of the main body 124 and the detection module 200 is arranged on the entire brush as one section.

That is, the arrangement of the detection module 200 is not different for each section as in FIG. 13(a) to 16(d), but the detection module 200 is arranged in the same form in each cross section.

FIG. 17(a) and 17(b) show cross-sections taken along line S9. The detection module 200 is arranged in the entire main body 124, while the detection module 200 is not arranged in the protrusions 126. FIG. 17(a) and 17(b) show embodiments in which the forms of the detection module 200 arranged in the main body 124 are different, respectively.

FIG. 17(a) shows an embodiment where, in the detection module 200 arranged along the entire longitudinal direction of the main body 124, the content of the detection component 210 included in the detection module 200 becomes higher as it is closer to the outer side portion 124b of the main body 124.

FIG. 17(b) shows an embodiment where, in the detection module 200 arranged along the entire longitudinal direction of the main body 124, the same content of the detection component 210 is included in both the inner side portion 124a and the outer side portion 124b.

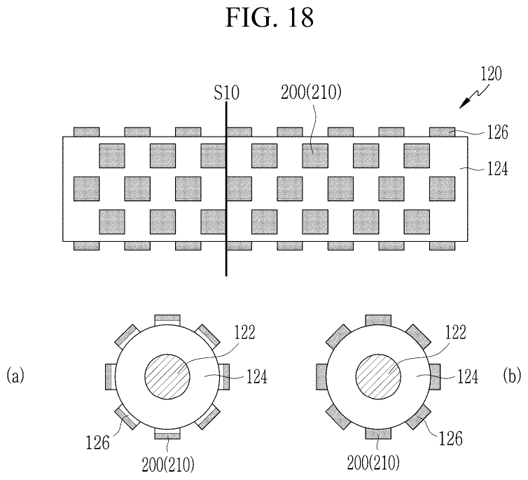

FIG. 18(a) and 18(b) show cross-sections taken along line S10. The detection module 200 is arranged in all of the plurality of protrusions 126, while the detection module 200 is not arranged in the main body 124. FIG. 18(a) and 18(b) show different embodiments of the detection module 200 arranged in the protrusions 126.

FIG. 18(a) shows an embodiment in which the detection module 200 arranged in the protrusions 126 has different contents of the detection component 210 depending on the distance from the main body 124, and the detection module 200 includes a higher content of the detection component 210 as it is farther from the main body 124.

FIG. 18(b) shows an embodiment in which the detection module 200 arranged in the protrusions 126 includes the same content of the detection component 210 throughout the entire detection module 200, regardless of the distance from the main body 124.

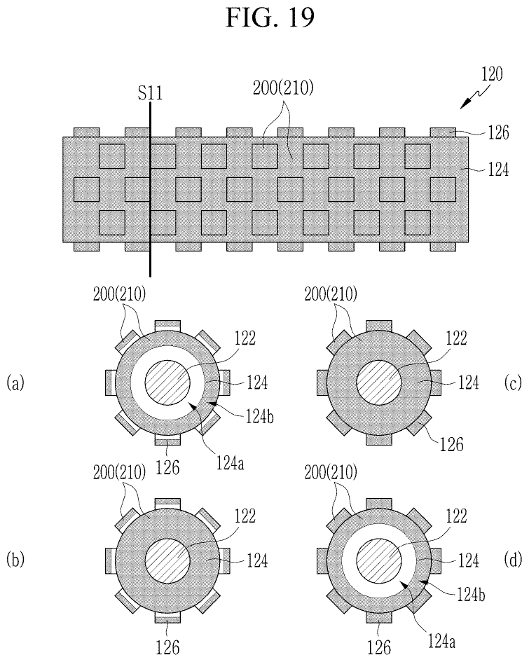

FIG. 19(a) to 19(d) show cross sections taken along line S11. FIG. 19(a) to 19(d) show various embodiments of the brush 120 in which the detection module 200 is arranged throughout the main body 124 and the protrusions 126.

The brush 120 shown in FIG. 19(a) corresponds to a case where the detection module 200 arranged in the protrusions 126 has a higher content of the detection component 210 as it is closer to the upper end of the detection module 200, and the detection module 200 arranged in the main body 124 has a higher content of the detection component 210 included in the detection module 200 as it is closer to the outer side portion 124b of the main body 124.

In the case of the brush 120 shown in FIG. 19(b), the detection module 200 arranged in the main body 124 includes the same content of the detection component 210 throughout, and the detection module 200 arranged in the protrusions 126 includes a higher content of the detection component 210 as it is farther from the main body 124.

FIG. 19(c) shows an embodiment in which the detection module 200 arranged in both the main body 124 and the protrusions 126 includes the same content of the detection component 210.

FIG. 19(d) shows an embodiment in which the detection module 200 arranged in the main body 124 has a higher content of the detection component 210 included in the detection module 200 as it is closer to the outer side portion 124b of the main body 124. The detection module 200 arranged in the protrusions 126 includes the same content of the detection component 210 throughout the entire detection module 200, regardless of the distance from the main body 124.

The brush 120 according to the present disclosure may include the detection module 200 arranged at various locations, as in the embodiments described with reference to FIG. 13(a) to 19(d).

The degree of contamination of the brush 120 can be more efficiently determined by considering the location of the detection module 200 arranged in the brush 120 depending on the contamination pattern.

While the present disclosure is described in connection with what is presently considered to be practical embodiments, the present disclosure is not limited to the disclosed embodiments. The present disclosure covers various modifications and equivalent arrangements included within the spirit and scope of the appended claims.

What is claimed is:

1. A contaminant detection device comprising:
a contact module configured to contact a wafer;
a detection module on the contact module, the detector being configured to change color by reacting with a metal ion; and
a sensing module configured to sense a color change of the detection module.

2. The contaminant detection device of claim 1, further comprising a head configured to mount the wafer thereon,
wherein the contact module comprises a polishing pad configured to face one surface of the wafer mounted on the head, and
wherein the detection module is on the polishing pad to be exposed toward one surface of the wafer.

3. The contaminant detection device of claim 2, wherein the detection module forms at least one of a point and a line.

4. The contaminant detection device of claim 2, wherein the polishing pad comprises a groove having a step from one surface in contact with the wafer.

5. The contaminant detection device of claim 4, wherein the detection module is exposed to at least a portion of one surface of the polishing pad and the groove.

6. The contaminant detection device of claim 1, wherein the contact module comprises a pair of brushes,
wherein each of the pair of brushes comprises:
a core configured to rotate about a longitudinal axis of the core;
a main body surrounding the core; and
a plurality of protrusions protruding from the main body, and
wherein the detection module comprises a detection component configured to change color by reacting with the metal ion.

7. The contaminant detection device of claim 6, wherein the detection module is in at least a portion of the main body and the plurality of protrusions.

8. The contaminant detection device of claim 6, wherein the detection module is in the main body, and the detection module comprises the same content of the detection component in each of:
an inner side portion, which is adjacent to an inner side surface where the main body is in contact with the core; and
an outer side portion, which is adjacent to an outer surface where the main body is in contact with the plurality of protrusions.

9. The contaminant detection device of claim 6, wherein the detection module is in the main body, and the detection module further comprises different contents of the detection component in each of:
an inner side portion, which is adjacent to an inner side surface where the main body is in contact with the core; and
an outer side portion, which is adjacent to an outer surface where the main body is in contact with the plurality of protrusions.

10. The contaminant detection device of claim 6, wherein the detection module is in the plurality of protrusions, and
wherein the detection module comprises different contents of the detection component depending on a distance from the main body.

11. The contaminant detection device of claim 6, wherein the detection module is in the plurality of protrusions, and
wherein the detection module comprises the same content of the detection component throughout the detection module.

12. A contaminant detection device comprising:
a head configured to mount a wafer thereon and rotate about a head axis;
a detection module configured to react with a metal ion;
a polishing pad on which the detection module is disposed to be exposed toward one surface of the wafer; and
a sensing module connected to the head and configured to sense a color change of the detection module.

13. The contaminant detection device of claim 12, wherein the polishing pad comprises:
a top pad having an upper surface in contact with the wafer;
a sub-pad below the top pad; and
a groove having a step with the upper surface of the top pad and having a concentric circular form on the polishing pad.

14. The contaminant detection device of claim 13, wherein the detection module is on the top pad to correspond to at least a portion of a surface forming the groove.

15. The contaminant detection device of claim 13, wherein the detection module is on the polishing pad to correspond to at least a portion of the upper surface of the top pad.

16. The contaminant detection device of claim 12, wherein the sensing module comprises:
a light source configured to irradiate a beam;
an optical window mounted on the head and configured to allow the beam to enter toward the polishing pad; and
a spectrometer configured to receive the beam reflected from the polishing pad and re-entering through the optical window and configured to measure a spectrum of the beam.

17. The contaminant detection device of claim 12, further comprising:
a head driver configured to rotate the head about the head axis;
a platen on which the polishing pad is fixed on an upper side; and
a platen driver configured to rotate the platen about a platen axis.

18. A contaminant detection device comprising:
a brush comprising a detection module in at least a portion of a main body and a plurality of protrusions, wherein the detection module comprises a detection component configured to react with a metal ion;
a cleaning module configured to clean the brush; and
a sensing module that is mounted on the cleaning module and senses a color change of the detection module.

19. The contaminant detection device of claim 18, wherein the contaminant detection device further comprises a sensing module, and
wherein the sensing module comprises:
a light source configured to irradiate a beam;
an optical window arranged on one side of a cleaner to face the brush and configured to allow the beam to enter toward the brush; and
a spectrometer configured to receive the beam reflected from the brush and re-entering through the optical window and configured to measure a spectrum of the beam.

20. The contaminant detection device of claim 18, wherein the cleaning module comprises:
a cleaner in contact with the brush on one side and configured to clean the brush; and
a supporter connected to the other side of the cleaner and support the cleaner.
